(19) United States
(12) Patent Application Publication
(10) Pub. No.: US 2018/0033901 A1
(43) Pub. Date: Feb. 1, 2018

(54) SEMI TRANSPARENT BACK CONTACT AND SOLAR CELL USING THE SAME, AND A METHOD OF MANUFACTURING THEM

(71) Applicant: KOREA INSTITUTE OF ENERGY RESEARCH, Daejeon (KR)

(72) Inventors: Jun Sik Cho, Daejeon (KR); Jae Ho Yun, Daejeon (KR); Se Jin Ahn, Daejeon (KR); Jihye Gwak, Daejeon (KR); Jin Su Yoo, Daejeon (KR); Seung Kyu Ahn, Daejeon (KR); Joo Hyung Park, Daejeon (KR); Young Joo Eo, Daejeon (KR); A Ra Cho, Daejeon (KR); Ki Hwan Kim, Daejeon (KR)

(21) Appl. No.: 15/341,725

(22) Filed: Nov. 2, 2016

(30) Foreign Application Priority Data
Aug. 1, 2016 (KR) 10-2016-0098051

(51) Int. Cl. H01L 31/0224; H01L 31/032; H01L 31/0216; H01L 31/18

(52) U.S. Cl. CPC H01L 31/022466; H01L 31/022441; H01L 31/1884; H01L 31/0322; H01L 31/022433; H01L 31/02168

(57) ABSTRACT

The invention relates to a semitransparent back electrode, a solar cell using the same, and a method for manufacturing them and, more specifically, to a technique for solving a performance decrease problem caused by increase of resistance of a conventional semitransparent solar cell. A method for manufacturing a semitransparent back electrode of a solar cell according to the invention includes depositing a transparent back electrode on a substrate, and forming a semitransparent molybdenum electrode layer on the back electrode. Accordingly, a BSF effect can be expected by applying a molybdenum layer locally or restrictively as a thin film, and the transparency is secured.

### CROSS-REFERENCE TO RELATED APPLICATION

This application claims priority to and the benefit of Korean Patent Application No. 10-2016-0098051, filed on Aug. 1, 2016, the disclosure of which is incorporated herein by reference in its entirety.

### BACKGROUND OF THE INVENTION

### Field of the Invention

The present invention relates to a semitransparent back electrode, a solar cell using the same, and a method for manufacturing them and, more specifically, to a technique for solving a performance decrease problem caused by increase of resistance of a conventional semitransparent solar cell.

### Description of the Related Art

A solar cell is a device which converts light energy into electric energy, and gets a lot of attention as a green future energy source. The solar cell and a power generation system receive solar light and immediately generate electricity using a solar cell including a semiconductor, dyes, and substances such as polymers by a technique of directly converting solar energy into electric energy. Specifically, the solar cell has a PN junction structure in which a P (positive) type semiconductor is joined to an N (negative) type semiconductor. When solar light is input to such a solar cell, holes and electrons are generated in the semiconductor by energy of the incident solar light. In this case, the holes move to the P-type semiconductor and the electrodes move to the N-type semiconductor to generate potential by electric field generated from the PN junction.

The solar cell may be classified into a substrate type solar cell and a thin film type solar cell. The substrate type solar cell is manufactured using a semiconductor material itself such as silicon as a substrate, and the thin film type solar cell is manufactured by forming a semiconductor layer on a substrate such as glass in a thin film form. Recently, as illustrated in FIG. 1, efficiency has been improved through development of a solar cell using a CIGS light absorption layer.

Recently, a technique of making such a solar cell transparent has been devoted. When a certain level of high light transmittance is secured in a solar cell, it can be used in various applications ranging from a building, a window of a vehicle to sunglasses, and a lot of demand is expected.

In order to make a transparent solar cell, instead of an opaque molybdenum (Mo) back electrode, oxide-based transparent electrodes such as ITO, FTO, AZO, and BZO with satisfactory light transmittance can be applied. In this case, there is a problem that gallium oxide (GaOₓ) is formed on a light absorption layer interface of the oxide-based transparent electrodes and a CIGS-based light absorption layer, charge movement is obstructed, serial resistance is increased, and performance of the solar cell is drastically decreased.

In addition, at the time of using a Mo electrode, a BSF (back surface field) effect based on formation of MoSe₂ is helpful for solar cell performance, but there is a problem that performance is decreased due to no BSF effect when applying an oxide-based transparent conductive layer.

Hereinafter, a conventional technique similar to an object and a configuration of the invention is described.

Korean Patent Publication No. 10-2016-0049214 ‘TRANSPARENT THIN FILM TYPE SOLAR CELL MODULE AND MANUFACTURING METHOD THEREOF’ relates to a transparent thin film type solar cell module which can be used as a window and a door of a building by securing both of improvement of light conversion efficiency and solar light transparent characteristics in a solar cell using a metal material for a light absorption layer such as copper-indium-gallium-selenide (CIGS) or CdTe solar cell, and discloses a method for manufacturing a transparent thin film type solar cell module and a transparent thin film type solar cell module manufactured by the manufacturing method, comprising: a process of preparing a glass substrate; a process of forming an n-type transparent conductive film; a process of performing first scribing of dividing the transparent conductive film into unit cells; a process of forming an n-type buffer layer; a process of forming a p-type light absorption layer forming a p-n junction layer and the buffer layer; a process of performing second scribing of restricting an area of the p-n junction layer before the transparent conductive film; a process of forming a back electrode; and a process of performing third scribing before the transparent conductive film. In Patent No. 10-2016-0049214, a structure in which incident solar light is first input to the glass substrate is provided, and three-step of scribing for modularity are re-disposed, thereby providing a structure of providing a space in which the incident light can pass by adjusting a cell division line width in the third scribing, to secure transparency, but there is a problem that it is difficult to secure sufficient transmittance only by solar light passing through the scribing.

Korean Patent Publication No. 10-2009-0004262 ‘METHOD FOR MANUFACTURING CIGS SOLAR CELL IN WHICH BACK ELECTRODE IS PATTERNED’ relates to a method for manufacturing a solar cell for improving efficiency of a CIGS solar cell by nano-patterning on a back electrode film deposited before forming a CIGS film using anodic oxidation and, more specifically, to a method in which an Mo is deposited on a glass substrate, and then SiO₂ and Al are sequentially deposited, to form nano-patterning by etching an SiO₂ film and Mo using a porous anodic alumina (PAA) film as an etching mask through anodic oxidation. In the case of the existing nano-patterning, nanoimprint and nanosphere lithography equipment is expensive, and thus there is a problem of increase in cost, but Patent No. 10-2009-0004262 has improved economical efficiency. A PAA method was studied for use as a template when forming a nanorod. In that case, a control of an accurate template form is necessary, but in the invention, patterning itself is important, and thus the accurate control is not necessary. In terms of improving efficiency by increasing a BSF effect by broadening a contact area of the CIGS thin film and Mo, the patent has similarity with the invention to be described later, but the broadening of the contact area is very different from the object and embodiment principle of the present invention in drastically decreasing transparency.

Korean Patent Publication No. 10-2015-0094944 ‘METHOD FOR FORMING CONNECTION ELECTRODE OF CIGS-BASED SOLAR CELL USING GRAPHENE BACK ELECTRODE’ relates to a technique of a CIGS-based solar cell using a graphene back electrode and a manufacturing method thereof. Differently from the conventional Mo back electrode, it is possible to absorb solar light on both sides, and it is possible to manufacture a flexible solar cell. Patent No. 10-2015-0094944 discloses a CIGS-based solar cell using a graphene back electrode comprising: a lower substrate; a graphene back electrode; a CIGS-based light absorption layer [CuIn₁₋ₓGa(S_{y}Se_{1-y})₂, where 0≦x≦1, 0≦y≦1]; a buffer layer; a transparent front electrode; and a front grid. However, the object to raise light transparency is similar with that of the present invention, but the configuration is very different.

### CITATION LIST

Patent 1: Korean Patent Publication No. 10-2016-0049214 ‘TRANSPARENT THIN FILM TYPE SOLAR CELL MODULE AND MANUFACTURING METHOD THEREOF’, PUBLICATION DATE: May 9, 2016

Patent 2: Korean Patent Publication No. 10-2009-0004262 ‘METHOD FOR MANUFACTURING CIGS SOLAR CELL IN WHICH BACK ELECTRODE IS PATTERNED’, PUBLICATION DATE: Jan. 12, 2009

Patent 3: Korean Patent Publication No. 10-2015-0094944 ‘METHOD FOR FORMING CIGS-BASED SOLAR CELL USING GRAPHENE BACK ELECTRODE’, PUBLICATION DATE: Aug. 20, 2015

### SUMMARY OF THE INVENTION

In development of a transparent solar cell, it is possible to secure transparency using an oxide-based transparent conductive film instead of an opaque molybdenum (Mo) electrode.

When the oxide-based transparent conductive film is applied, as described above, transparent electrodes such as ITO, FTO, AZO, and BZO can be applied, but there is a problem that gallium oxide (GaOₓ) is formed on a light absorption layer interface of the oxide-based transparent electrodes and a CIGS-based light absorption layer, charge movement is obstructed, serial resistance is increased, and performance of the solar cell is drastically decreased.

In addition, at the time of using a Mo electrode, a BSF effect based on formation of MoSe₂ is helpful for solar cell performance, but there is a problem that performance is decreased due to no BSF effect at the time of applying an oxide-based transparent conductive layer.

A method for manufacturing a semitransparent back electrode of a solar cell according to the invention includes (S1000) depositing a transparent back electrode 200 on a substrate 100, and (S2000) forming a semitransparent molybdenum electrode layer 210 on the back electrode 200. Accordingly, a BSF effect can be expected by applying a molybdenum layer locally or restrictively as a thin film, thereby solving the problems.

### BRIEF DESCRIPTION OF THE DRAWINGS

FIG. 1 is a cross-sectional view of main portions of the conventional CIGS-based thin film solar cell of prior art;

FIG. 2 is a photograph illustrating a state of forming gallium oxide (GaOₓ) when an ITO electrode is applied instead of a molybdenum (Mo) electrode;

FIG. 3 is a cross-sectional view of main portions of a first embodiment of the invention;

FIG. 4 is an exploded perspective view of main portions of the first embodiment of the invention;

FIG. 5 is a perspective view of a second embodiment of the invention;

FIG. 6 is a perspective view of a third embodiment of the invention;

FIG. 7 is a perspective view of main portions illustrating the other type of a grid of the third embodiment of the invention;

FIG. 8 is a cross-sectional view of main portions of the third embodiment of the invention;

FIG. 9 is a flowchart illustrating a method for manufacturing a solar cell of the invention; and

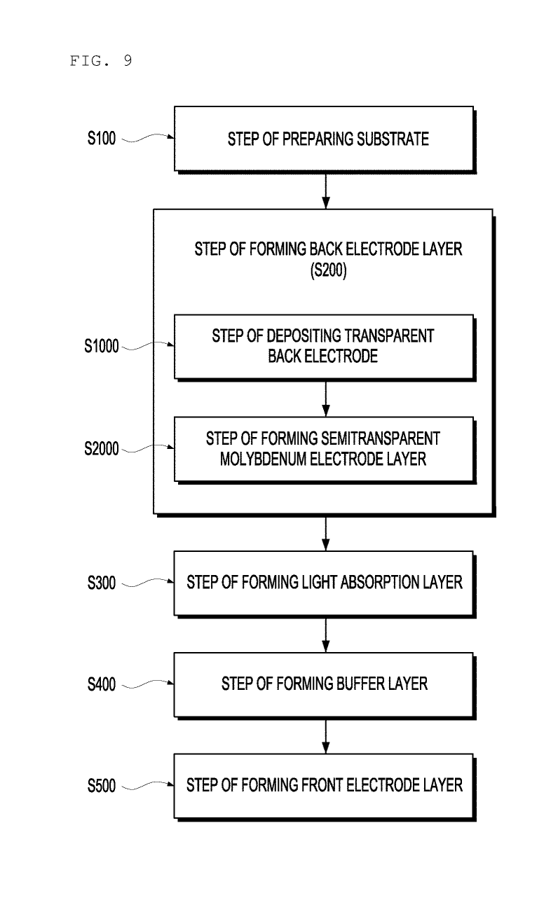

FIG. 10 is a performance comparison graph and table in which the solar cell of the invention is compared with a control group using only ITO instead of a molybdenum electrode.

### DETAILED DESCRIPTION OF THE PREFERRED EMBODIMENTS

Hereinafter, the invention will be described in detail with reference to the accompanying drawings.

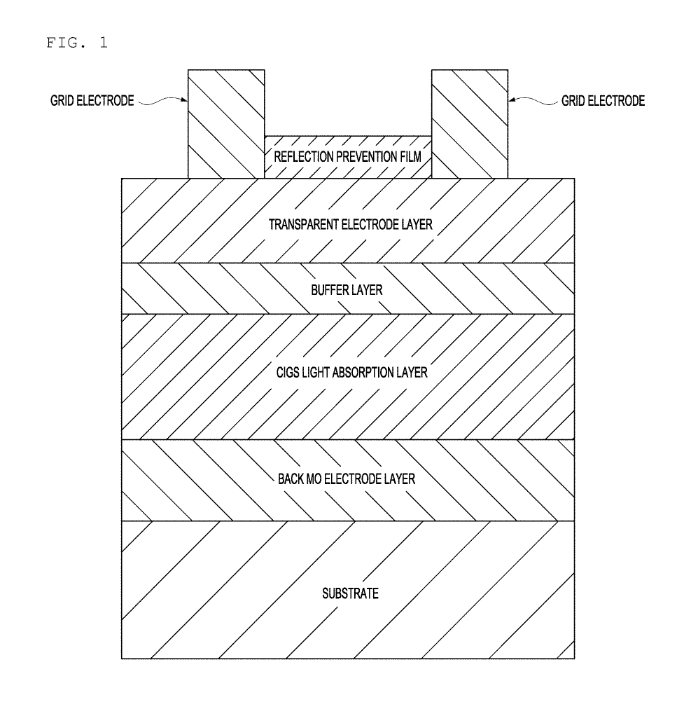

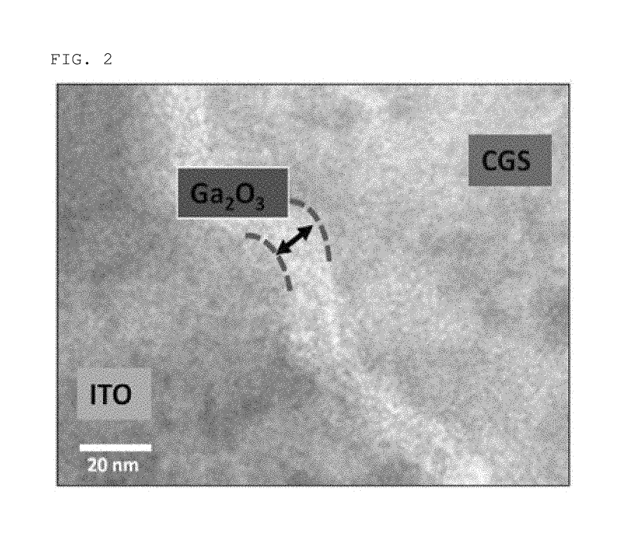

As illustrated in FIG. 1, in a CIGS-based thin film solar cell, a molybdenum (Mo) electrode is deposited as a back electrode on a substrate, a CIGS light absorption layer, a buffer layer, and a transparent electrode layer are sequentially deposited thereon, and a grid electrode, a reflection prevention film, or the like is selectively installed on the transparent electrode layer. In order for such a CIGS-based thin film solar cell to have transparency, the opaque back molybdenum (Mo) electrode has to be changed to a transparent electrode. The transparent electrode may be an oxidation transparent electrode such as AZO (Al doped zinc oxide), BZO (B doped zinc oxide), GZO (Ga doped zinc oxide), ZnO, ITO (indium tin oxide), In₂O₃, FTO (F doped tin oxide), gallium oxide, aluminum oxide, lead oxide, copper oxide, titanium oxide, iron oxide, and tin dioxide. However, when such an oxidation transparent electrode is applied, as illustrated in FIG. 2, there is a problem that gallium oxide (GaOₓ) is formed on an interface of the oxidation transparent electrodes and the CIGS light absorption layer to obstruct charge movement to increase serial resistance to drastically decrease performance of a solar cell. FIG. 2 is a photograph illustrating a state where a gallium oxide (GaOₓ) is formed when applying an ITO electrode instead of a molybdenum (Mo) electrode, and it can be seen that a GaOₓ layer is formed by an interface reaction of a CGS light absorption layer and an ITO thin film.

In addition, when using the Mo electrode, a back surface field effect (hereinafter, referred to as a BSF effect) based on formation of MoSe₂ on the interface drastically improves the performance of the solar cell. However, when using the oxide-based transparent conductive layer described above, there is a problem that the performance is decreased due to no BSF effect.

The present invention provides a method for manufacturing a semitransparent back electrode of a solar cell, including: a step (S1000) of depositing a transparent back electrode 200 on a substrate 100; and a step of (S2000) of forming a semitransparent molybdenum electrode layer 210 on the transparent back electrode 200. According to the method, the transparent back electrode 200 is formed on the glass substrate 100, and the semitransparent molybdenum electrode layer 210 is formed on the transparent back electrode 200, thereby forming a semitransparent back electrode of a solar cell.

In other words, the oxide-based transparent conductive layer is used to secure light transparency, and the molybdenum electrode is restrictively applied to obtain the BSF effect. In addition, the restrictively applied semitransparent molybdenum electrode layer 210 suppresses generation of gallium oxide (GaOₓ) to embody higher photoelectric efficiency as compared with the case of applying only the oxide-based transparent conductive layer. However, as described above, since the molybdenum electrode is opaque, the transparency of the restrictively applied semitransparent molybdenum electrode 210 has to be adjusted.

First, in the method for manufacturing a semitransparent back electrode of a solar cell according to the invention, the transparent back electrode 200 in the step (S1000) of depositing of the transparent back electrode 200 on the substrate 100 made of glass or the like preferably includes at least one material selected from AZO (Al doped zinc oxide), BZO (B doped zinc oxide), GZO (Ga doped zinc oxide), ZnO, ITO (indium tin oxide), In₂O₃, FTO (F doped tin oxide), gallium oxide, aluminum oxide, lead oxide, copper oxide, titanium oxide, iron oxide, and tin dioxide.

The transparent back electrode 200 in the step (S1000) of depositing of the transparent back electrode 200 on the substrate 100 may be deposited by selecting one method of RF magnetron sputtering, DC magnetron sputtering, MF magnetron sputtering, thermal evaporation, electron beam evaporation, and thermal spraying.

As described above, in order to obtain transparency required in the thin film CIGS-based solar cell, the light transparency of the semitransparent molybdenum electrode layer 210 has to be adjusted.

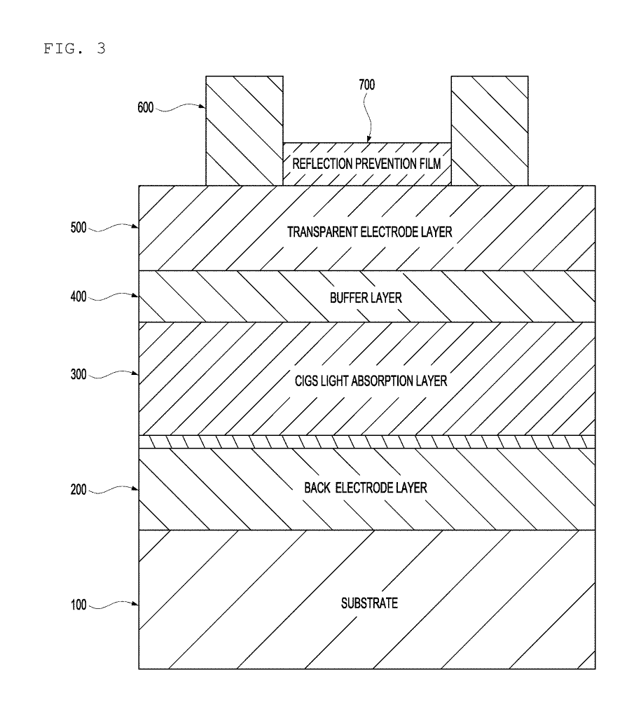

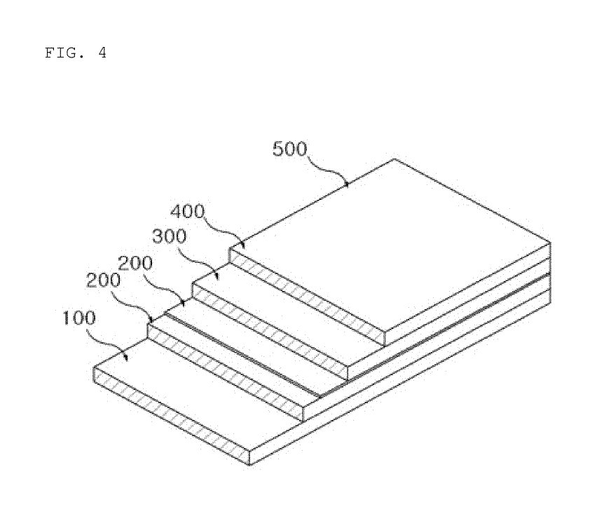

FIG. 3 is a cross-sectional view of main portions of a first embodiment of the invention, and FIG. 4 is an exploded perspective view of main portions of the first embodiment. As the first embodiment for adjusting the transparency of the semitransparent molybdenum electrode layer 210, in the step (S2000) of forming the semitransparent molybdenum electrode layer 210 on the back electrode 200, molybdenum is deposited as an ultrathin film with a thickness of 2 nm to 50 nm. In other words, the opaque molybdenum layer is deposited as the ultrathin film to allow light to pass some extent. As an advantage of the embodiment, since the oxide-based transparent conductive layer does not come in direct contact with the CIGS light absorption layer, it is possible to effectively prevent gallium oxide (GaOₓ) from being generated, and it is possible to expect a high-level of BSF effect.

However, since the opaque molybdenum is deposited overall, loss of transmittance is somewhat large, and since the thin film is formed very thin, it is not easy to secure uniformity and repeatability.

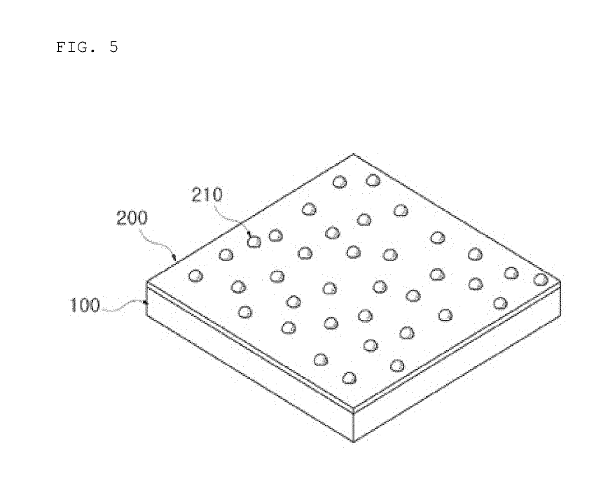

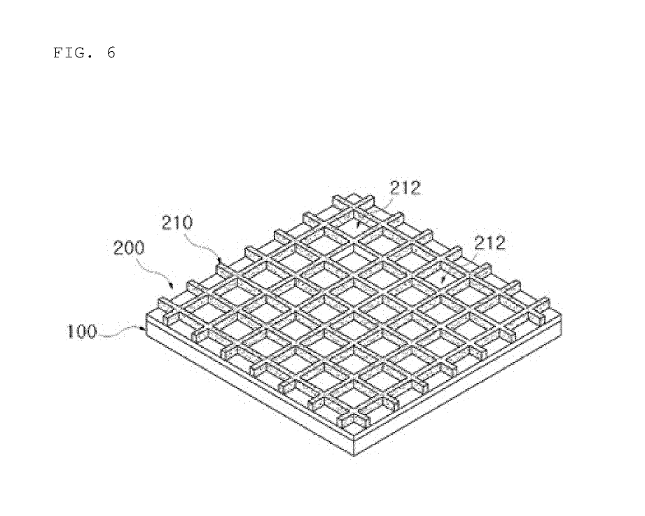

FIG. 5 is a perspective view of main portions of a second embodiment of the invention, and FIG. 6 is a perspective view of main portions of a third embodiment of the invention. As a second embodiment for adjusting transparency of the semitransparent molybdenum electrode layer 210, the molybdenum electrode layer 210 may be formed by depositing molybdenum particles in an island 211 shape. In this case, it is preferable that molybdenum is discontinuously deposited to deposit molybdenum particles in a discontinuous island 211 shape. For example, formation of island may be promoted through repetition of a discontinuous process such as cutoff by a shutter operation after deposition for 10 seconds. The size and shape of the island (211) of the molybdenum particles may be adjusted according to a deposition time and frequency of discontinuation.

Alternatively, a method of depositing the molybdenum thin film and then performing heat treatment thereon to condense the molybdenum particles in the island 211 shape is possible.

Preferably, the thickness of the island 211 formed by the molybdenum particles is 1 to 20 nm and the diameter thereof is 1 to 100 nm, but the size of the island 211 may be adjusted in the appropriate level of the light transmittance and the photoelectric efficiency.

FIG. 6 is a perspective view of main portions of a third embodiment of the invention. As the third embodiment for adjusting transparency of the semitransparent molybdenum electrode layer 210, in the step (S2000) of forming the semitransparent molybdenum electrode layer 210 on the back electrode 200, molybdenum may be formed into a thin film layer having a grid layer or a pattern having an opening portion 212.

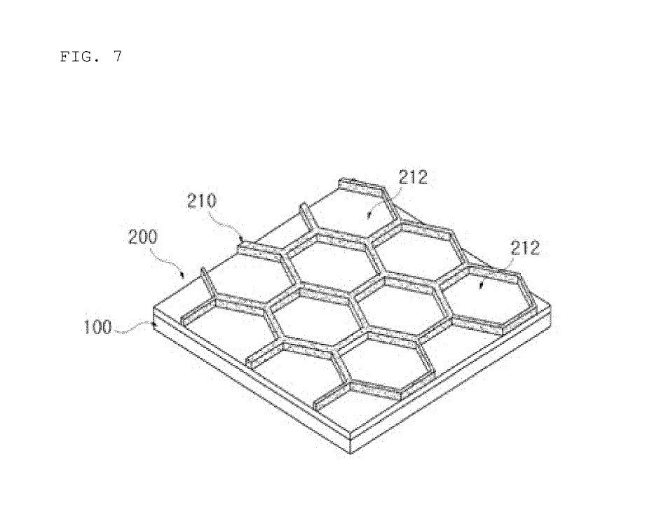

The grid shape and pattern preferably have a regular polygonal or circular unit structure to secure uniform transmittance. FIG. 6 illustrates an embodiment in which the unit structure is rectangular, and FIG. 7 illustrates an embodiment in which the unit structure is a grid structure in a honeycomb shape.

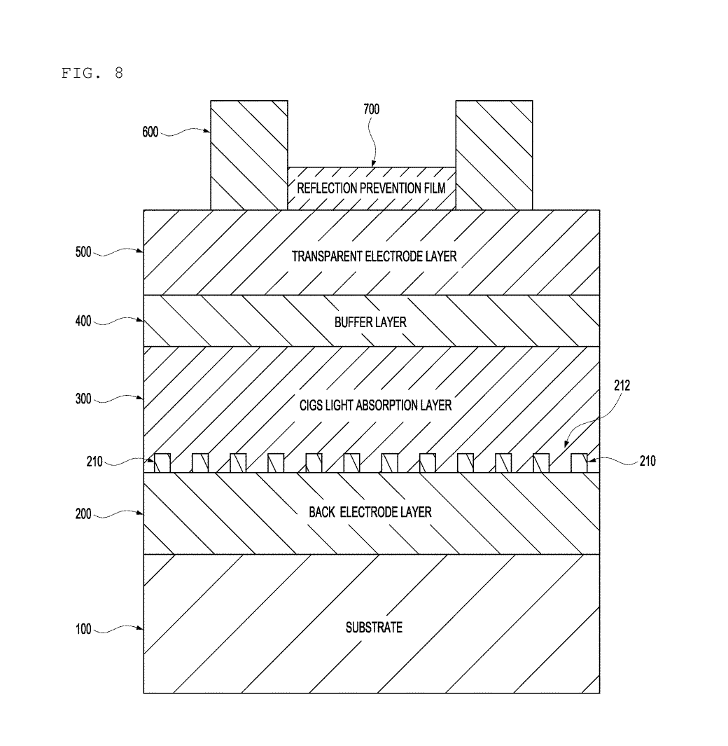

In the embodiment, differently from the former embodiments, there are advantages that it is possible to deposit a metal thin film with a sufficient thickness, which makes it easy to secure reproducibility, and particularly, it is possible to easily secure and adjust transparency through adjustment of an opening ratio of the opening portion 212 illustrated in FIG. 6 to FIG. 8. In addition, it is possible to form BSF according to local generation of MoSe2, and thus it is advantageous in terms of photoelectric efficiency.

The thin film layer having the grid layer or pattern having the opening portion 212 may be formed by one or more methods selected from patterning using laser scribing, photoresist and a mask after depositing molybdenum. In the process of patterning using laser scribing, photoresist and a mask, it is possible to adjust an opening ratio for adjusting the size of the opening portion 212, and photoelectric efficiency and transparency of the CIGS thin film solar cell are determined according to the adjusted opening ratio.

The present invention provides the method for manufacturing a semitransparent back electrode and further provides a method for manufacturing a solar cell including the semitransparent back electrode.

A method for manufacturing a solar cell according to the invention comprises: (i) a step (S100) of preparing a substrate 100; (ii) a step (S200) of forming a back electrode layer 200 on the substrate; (iii) a step (S300) of forming a CIGS light absorption layer 300 including copper, indium, gallium, and selenium on the back electrode layer 200; (iv) a step (S400) of forming a buffer layer 400 including at least one of CdS ZnS, and InOH on the light absorption layer 300; (v) a step (S500) of forming a front electrode layer 500 including at least one of zinc oxide, gallium oxide, aluminum oxide, indium oxide, lead oxide, copper oxide, titanium oxide, tin dioxide, iron oxide, tin dioxide, and indium tin oxide on the buffer layer 400, wherein (ii) the step (S200) of forming the back electrode layer 200 on the substrate is the method for manufacturing a semitransparent back electrode including the semitransparent molybdenum electrode layer 210 described above.

The thickness of the light absorption layer 300 is preferably 0.1 μm to 2 μm considering transmittance. The light absorption layer 300 may include at least one of a CIS/CIGS-based compound group including Cu—In—Se, Cu—In—S, Cu—Ga—S, Cu—Ga—Se, Cu—In—Ga—Se, Cu—In—Ga—(S,Se), and Cu—In—Al—Ga—(S,Se).

In addition, the light absorption layer 300 may be formed using at least one method of coevaporation, sputtering, metal organic chemical vapor deposition (MOCVD), molecular beam epitaxy (MBE), electrodeposition, screen printing, and particle deposition.

The buffer layer 400 includes at least one of CdS, InxSey, Zn(O,S,H)x, In(OH)xSy, ZnInxSey, and ZnSe, and is preferably formed using chemical bath deposition (CBD), electrodeposition, coevaporation, sputtering, atomic layer epitaxy, chemical vapor deposition (CVD), metal organic chemical vapor deposition (MOCVD), molecular beam epitaxy (MBE), spray pyrolysis, ion layer gas reaction (ILGAR), and pulsed laser deposition.

The front electrode layer 500 is an oxide-based transparent electrode, and may be formed of AZO (Al doped zinc oxide), BZO (B doped zinc oxide), GZO (Ga doped zinc oxide), ZnO, ITO (indium tin oxide), In2O3, FTO (F doped tin oxide), gallium oxide, aluminum oxide, lead oxide, copper oxide, titanium oxide, iron oxide, and tin dioxide, as applied to the back electrode of the invention.

The reflection prevention film 700 may be formed of MgF2, and the grid electrode layer 600 may include at least one of Al, Ag, Ni, Cu, Pt, Au and Mo. The grid electrode layer 600 is also formed of an opaque material, and thus is preferably configured to be thin or is preferably configured considering an overall shading rate.

According to the manufacturing method described above, the invention provides a solar cell including a substrate 100, a back electrode layer 200 which is formed on the substrate 100, a light absorption layer 300 which is formed on the back electrode layer 200 and includes copper, indium, gallium, and selenium, a buffer layer 400 which is formed on the light and includes at least one of CdS, CdZnS, ZnS, ZnOS, Zn(OH,S), ZnS(O,OH), ZnSe, ZnInS, ZnlnSe, ZnMgO, Zn(Se,OH), ZnSnO, ZnO, InSe, InOH, In(OH,S), In(OOH,S), and In(S,O), and a transparent electrode layer 500 which is formed on the buffer layer 400, wherein the back electrode layer 200 is formed of a semitransparent back electrode having a semitransparent molybdenum electrode layer 210.

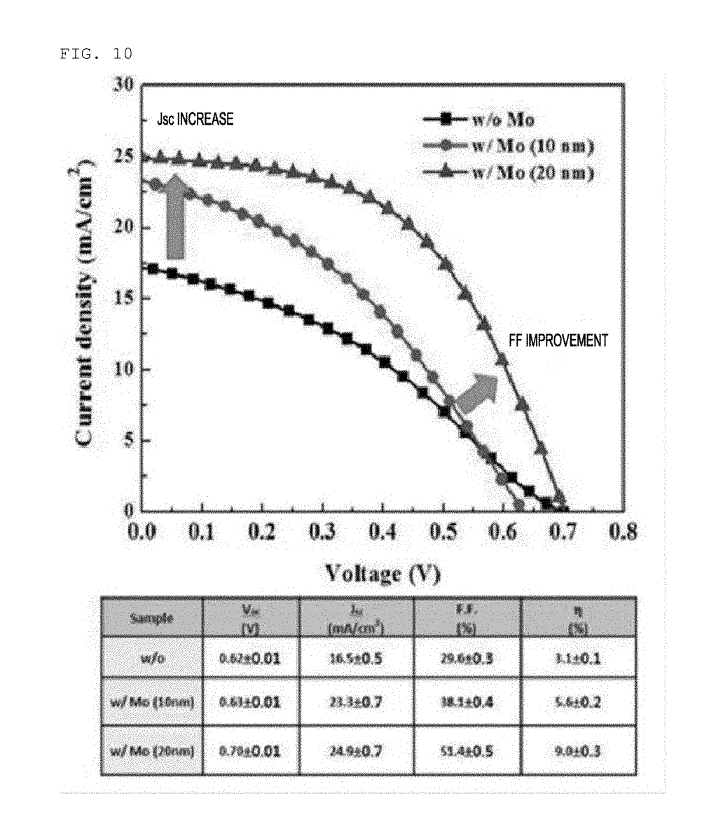

FIG. 10 illustrates a performance comparison graph and table with respect to a control group (line -▪-) using only ITO instead of a molybdenum electrode as compared with the solar cell of the invention. As illustrated in the graph of FIG. 10, when molybdenum is deposited with 10 nm (line --), higher current density is seen at 0.7 V or lower, and when molybdenum is deposited with 20 nm (line -▴-), even higher current density is seen. In other words, when molybdenum is used in combination, it can be seen that an effect of increasing JSC (short-circuit current) for estimating the performance of a solar cell as compared with a sample of an electrode with only ITO. In addition, it can be seen that F.F (fill factor) which is one of important indicators of solar cell performance is 29.6±0.3% in an electrode sample with only ITO, but is increased to 38.1±0.4% at the time of depositing molybdenum with 10 nm, and is increased to 51.4±0.5% at the time of depositing molybdenum with 20 nm. In addition, it can be seen that, when only ITO is applied, photoelectric efficiency is 3.1±0.1%, but when molybdenum is applied together, photoelectric efficiency is increased to 5.6±0.2% at the time of depositing molybdenum with 10 nm, and is increased to 9.0±0.3% at the time of depositing molybdenum with 20 nm.

According to the measurement result, it can be seen that the performance of the solar cell is further improved as the deposition thickness of molybdenum gets thicker. In other words, in the case of the third embodiment of the invention using the grid/pattern structure, the deposition thickness of molybdenum can be sufficiently increased, the opening ratio is increased, the light transmittance is raised, and the deposition thickness of molybdenum is sufficiently secured, to further improve the performance of the solar cell.

According to the invention, in manufacturing a transparent CIGS-based thin film solar cell for photovoltaic power generation such as a window and door type solar cell and a vehicle sunroof solar cell, required transparency is secured, and a transparent CIGS-based thin film solar cell with low performance loss as compared with the conventional CIGS to which only molybdenum is applied.

FIG. 10 is a performance comparison graph and table with respect to a control group using only ITO instead of a molybdenum electrode as compared with the solar cell of the invention. As illustrated in the graph of FIG. 10, when molybdenum is deposited by 10 nm (line --), higher current density was represented at 0.7 V or lower, and when molybdenum is deposited by 20 nm, further higher current density can be seen. In other words, when molybdenum is used in combination, it can be seen that an effect of increasing JSC (short-circuit current) for estimating performance of a solar cell as compared with a sample of an electrode with only ITO. In addition, it can be seen that F.F (fill factor) which is one of important indicators of solar cell performance is 29.6±0.3% in an electrode sample with only ITO, but is increased to 38.1±0.4% at the time of depositing molybdenum with 10 nm, and is increased to 51.4±0.5% at the time of depositing molybdenum with 20 nm. In addition, it can be seen that, when only ITO is applied, photoelectric efficiency is 3.1±0.1%, but when molybdenum is applied together, photoelectric efficiency is increased to 5.6±0.2% at the time of depositing molybdenum with 10 nm, and is increased to 9.0±0.3% at the time of depositing molybdenum with 20 nm. According to the measurement result described above, in a third embodiment of the invention using a grid/pattern structure, it is possible to further improve performance of a solar cell by sufficiently securing a deposition thickness of molybdenum while raising light transmittance by increasing an opening ratio. In other words, when a grid or a pattern having an opening portion is applied as a semitransparent molybdenum electrode layer, there is an effect capable of adjusting photoelectric efficiency and light transmittance according to the application by adjusting an opening ratio of the opening portion and a deposition thickness of a molybdenum layer.

The invention has been described with reference to the accompanying drawings, it is merely one embodiment of various embodiments including the gist of the invention, the object of the invention is for a person skilled in the art to easily embody the invention, and it is apparent that the invention is not limited to only the embodiments described above. Accordingly, the scope of protection of the invention has to be interpreted by the following claims, and all technical spirits within the scope equivalent to modification, replacement, and substitution within the scope without departing from the gist of the invention are included in the scope of right of the invention. In addition, a part of configurations of the drawings is for more clearly describing the configurations, and it is apparent that the configurations are provided by exaggeration and reduction as compared with the actual configurations.

1. A method for manufacturing a semitransparent back electrode of a solar cell, comprising:
depositing a transparent back electrode on a substrate; and
forming a semitransparent molybdenum electrode layer on the back electrode.

2. The method for manufacturing a semitransparent back electrode of a solar cell according to claim 1, wherein the transparent back electrode in the depositing of the transparent back electrode on the substrate comprises at least one material selected from the group consisting of Al doped zinc oxide (AZO), B doped zinc oxide (BZO), Ga doped zinc oxide (GZO), ZnO, indium tin oxide (ITO), In₂O₃, F doped tin oxide (FTO), gallium oxide, aluminum oxide, lead oxide, copper oxide, titanium oxide, iron oxide, and tin dioxide.

3. The method for manufacturing a semitransparent back electrode of a solar cell according to claim 1, wherein the transparent back electrode in the depositing of the transparent back electrode on the substrate is deposited by selecting a method selected from the group consisting of RF magnetron sputtering, DC magnetron sputtering, MF magnetron sputtering, thermal evaporation, electron beam evaporation, and thermal spraying.

4. The method for manufacturing a semitransparent back electrode of a solar cell according to claim 1, wherein in the forming of the semitransparent molybdenum electrode layer on the back electrode, molybdenum is deposited as an ultrathin film with a thickness of 2 nm to 50 nm.

5. The method for manufacturing a semitransparent back electrode of a solar cell according to claim 1, wherein in the forming of the semitransparent molybdenum electrode layer on the back electrode, molybdenum is discontinuously deposited in a discontinuous island shape.

6. The method for manufacturing a semitransparent back electrode of a solar cell according to claim 1, wherein in the forming of the semitransparent molybdenum electrode layer on the back electrode, a molybdenum thin film is deposited and heat treatment is performed thereon to condense molybdenum particles in an island shape.

7. The method for manufacturing a semitransparent back electrode of a solar cell according to claim 5, wherein the thicknesses of the island-shaped molybdenum particles in the forming of the semitransparent molybdenum electrode layer on the back electrode are 1 to 20 nm.

8. The method for manufacturing a semitransparent back electrode of a solar cell according to claim 1, wherein in the forming of the semitransparent molybdenum electrode layer on the back electrode, molybdenum is formed into a thin film layer having a grid layer or a pattern having an opening portion.

9. The method for manufacturing a semitransparent back electrode of a solar cell according to claim 8, wherein the thin film layer having the grid layer or the pattern having the opening portion in the forming of the semitransparent molybdenum electrode layer on the back electrode is formed by one or more methods selected from the consisting of patterning using laser scribing, photo resist, and a mask after depositing molybdenum.

10. A method for manufacturing a solar cell, comprising:
(i) providing a substrate;
(ii) forming a semitransparent back electrode layer on the substrate according to the method of claim 1;
(iii) forming a copper-indium-gallium-selenide (CIGS) light absorption layer comprising copper, indium, gallium, and selenium on the back electrode layer;
(iv) forming a buffer layer comprising at least one selected from the group consisting of CdS, ZnS, and InOH on the CIGS light absorption layer; and
(v) forming a front electrode layer comprising at least one selected from the group consisting of zinc oxide, gallium oxide, aluminum oxide, indium oxide, lead oxide, copper oxide, titanium oxide, tin dioxide, iron oxide, tin dioxide, and indium tin oxide on the buffer layer.

11. A semitransparent back electrode of a solar cell, comprising: a transparent back electrode which is formed on a glass substrate; and a semitransparent molybdenum electrode layer which is formed on the transparent back electrode.

12. The semitransparent back electrode of a solar cell according to claim 11, wherein the transparent back electrode comprises at least one material selected from Al doped zinc oxide (AZO), B doped zinc oxide (BZO), Ga doped zinc oxide (GZO), ZnO, indium tin oxide (ITO), In₂O₃, F doped tin oxide (FTO), gallium oxide, aluminum oxide, lead oxide, copper oxide, titanium oxide, iron oxide, and tin dioxide.

13. The semitransparent back electrode of a solar cell according to claim 11, wherein the semitransparent molybdenum electrode layer is a molybdenum ultrathin film with a thickness of 2 nm to 50 nm.

14. The semitransparent back electrode of a solar cell according to claim 11, wherein the semitransparent molybdenum electrode layer is formed by depositing molybdenum particles in an island shape.

15. The semitransparent back electrode of a solar cell according to claim 14, wherein the thickness of the island formed by the molybdenum particles is 1 to 20 nm, and the diameter thereof is 1 to 100 nm.

16. The semitransparent back electrode of a solar cell according to claim 11, wherein the semitransparent molybdenum electrode layer is a thin film layer having a grid layer or a pattern having an opening portion.

17. A solar cell comprising:
a substrate;
a semitransparent back electrode layer according to claim 11 which is formed on the substrate;
a light absorption layer formed on the back electrode layer, said light absorption layer comprising copper, indium, gallium, and selenium;
a buffer layer which comprises at least one of selected from the group consisting of CdS, CdZnS, ZnS, ZnOS, Zn(OH,S), ZnS(O,OH), ZnSe, ZnInS, ZnlnSe, ZnMgO, Zn(Se,OH), ZnSnO, ZnO, InSe, InOH, In(OH,S), In(OOH,S), and In(S,O); and
a front electrode layer which is formed of a transparent material on the buffer layer.

18. The method for manufacturing a semitransparent back electrode of a solar cell according to claim 6, wherein the thicknesses of the island-shaped molybdenum particles in the forming of the semitransparent molybdenum electrode layer on the back electrode are 1 to 20 nm
